(19) United States
(12) Patent Application Publication
(10) Pub. No.: US 2019/0165001 A1
(43) Pub. Date: May 30, 2019

(54) ARRAY SUBSTRATE, METHOD OF MANUFACTURING THE SAME AND DISPLAY PANEL

(71) Applicants: BOE Technology Group Co., Ltd., Beijing (CN); Ordos Yuansheng Optoelectronics Co., Ltd., Inner Mongolia (CN)

(72) Inventors: Lei Yao, Beijing (CN); Dawei Shi, Beijing (CN); Wentao Wang, Beijing (CN); Lu Yang, Beijing (CN); Haifeng Xu, Beijing (CN); Lei Yan, Beijing (CN); Jinfeng Wang, Beijing (CN); Xiaowen Si, Beijing (CN); Fang Yan, Beijing (CN); Jinjin Xue, Beijing (CN); Lin Hou, Beijing (CN); Zhixuan Guo, Beijing (CN); Yuanbo Li, Beijing (CN); Xiaofang Li, Beijing (CN)

(21) Appl. No.: 16/011,901

(22) Filed: Jun. 19, 2018

(30) Foreign Application Priority Data
Nov. 27, 2017 (CN) 201711206103.3

(51) Int. Cl. H01L 27/12; H01L 29/423; H01L 29/417; G02F 1/1368

(52) U.S. Cl. CPC H01L 27/1222; H01L 29/42384; H01L 29/41733; G02F 2001/13685; H01L 27/1262; G02F 2201/121; G02F 2201/123; G02F 1/1368

(57) ABSTRACT

An array substrate, a method of manufacturing the same, and a display panel are provided, the array substrate includes a base substrate, and a pixel unit on the base substrate; and a reflective layer disposed on the base substrate and located in a portion of a region of the pixel unit, a surface of the reflective layer facing away from the base substrate includes a rugged structure.

### CROSS-REFERENCE TO RELATED APPLICATION

This application claims priority to Chinese Patent Application No. 201711206103.3 filed on Nov. 27, 2017 in the State Intellectual Property Office of China, the disclosure of which is hereby incorporated by reference in its entirety.

### TECHNICAL FIELD

The present disclosure relates to a field of display technology, and particularly to an array substrate, a method of manufacturing the same, and a display panel.

### DESCRIPTION OF THE RELATED ART

A thin film transistor liquid crystal display (TFT-LCD) includes a transmissive display device involving a light transmission effect. Particularly, for a portable device, its image displaying is subject to limitation to some extent in outdoor intensity-light condition. Ambient light intensity is so strong, that contents display by a portable device are difficult to identify. Usually, in order to improve the display effect in this condition, the display device is needed to increase brightness of backlight to maintain normal content display. However, this will not only accelerate the consumption of battery power and shorten standby time of the display device, but also cause additional damage to eyes.

Therefore, for a transmissive display in the art, display effect of the display panel is affected by the ambient light.

### SUMMARY

An embodiment of the present disclosure provides an array substrate comprising: a base substrate, and a pixel unit on the base substrate; and a reflective layer disposed on the base substrate and located in a portion of a region of the pixel unit, wherein, a surface of the reflective layer facing away from the base substrate comprises a rugged structure.

In some embodiments, the reflective layer is made of a metal material.

In some embodiments, the reflective layer is made of silver.

In some embodiments, the array substrate further comprising: a pixel electrode disposed on the base substrate and located in the pixel unit, wherein the reflective layer is disposed between the pixel electrode and the base substrate.

In some embodiments, the array substrate further comprising: a thin film transistor on the base substrate, wherein the thin film transistor comprises a gate electrode, an active layer, and a source/drain electrode, wherein the reflective layer is disposed in a same layer as any one of the gate electrode, the active layer, and the source/drain electrode.

In some embodiments, the reflective layer is disposed in the same layer as the active layer.

In some embodiments, the thin film transistor is a top-gate thin film transistor, and the array substrate further comprises: a light shielding layer between the thin film transistor and the base substrate; wherein an orthogonal projection of the gate electrode on the base substrate is located within an orthogonal projection of the light shielding layer on the base substrate or the orthogonal projection of the gate electrode on the base substrate coincides the orthogonal projection of the light shielding layer on the base substrate.

In some embodiments, the thin film transistor is a dual-gate thin film transistor.

In some embodiments, the array substrate of claim 4, further comprising: at least one of a passivation layer and an organic film layer provided between the reflective layer and the pixel electrode.

In some embodiments, the reflective layer in the pixel unit comprises a plurality of sub reflective layers spaced away from one another.

In some embodiments, the reflective layer in the pixel unit is in a mesh-like shape.

An embodiment of the present disclosure provides a display panel, comprising the array substrate according to the above embodiments.

An embodiment of the present disclosure provides a method of manufacturing an array substrate, comprising: providing a base substrate; and forming a reflective layer within a portion of a region of the base substrate where a pixel unit is to be formed, wherein, a surface of the reflective layer facing away from the base substrate comprises a rugged structure.

In some embodiments, the step of forming a reflective layer within a portion of a region of the base substrate where a pixel unit is to be formed comprises: depositing a reflective material layer on the whole base substrate; bombarding the reflective material layer with inert gas; and patterning the bombarded reflective material layer to form the reflective layer.

In some embodiments, the step of forming a reflective layer within a portion of a region of the base substrate where a pixel unit is to be formed comprises: depositing a reflective material layer on the whole base substrate; patterning the reflective material layer to form a reflective material pattern within the portion of the region of the base substrate where the pixel unit is to be formed; forming a photoresist pattern in a region of the base substrate where the reflective material pattern is not formed; bombarding the reflective material pattern with inert gas; and peeling off the photoresist pattern.

In some embodiments, the method further comprising: forming a thin film transistor on the base substrate, wherein the thin film transistor comprises a gate electrode, an active layer, and a source/drain electrode, wherein the reflective layer is formed in a same layer as any one of the gate electrode, the active layer, and the source/drain electrode.

In some embodiments, before forming a reflective layer within a portion of a region of the base substrate where a pixel unit is to be formed, the method further comprises: forming the active layer of the thin-film transistor by a patterning process, wherein, the reflective layer is formed in the same layer as the active layer of the thin film transistor.

In some embodiments, after forming a reflective layer within a portion of a region of the base substrate where a pixel unit is to be formed, the method further comprises: forming a pixel electrode within the region of the base substrate where the pixel unit is to be formed.

### BRIEF DESCRIPTION OF THE DRAWINGS

FIG. 1a shows a schematic planar view of an array substrate provided by an embodiment of the present disclosure;

FIG. 1b shows a schematic partial cross-sectional view of an array substrate provided by an embodiment of the present disclosure;

FIG. 1c shows a schematic partial cross-sectional view of an array substrate provided by an alternative embodiment of the present disclosure;

FIG. 1d shows a schematic partial cross-sectional view of an array substrate provided by an alternative embodiment of the present disclosure;

FIG. 2 shows a schematic partial cross-sectional view of an array substrate provided by another embodiment of the present disclosure;

FIG. 3a shows a schematic planar view of an array substrate provided by an alternative embodiment of the present disclosure;

FIG. 3b shows a schematic planar view of an array substrate provided by an alternative embodiment of the present disclosure;

FIG. 3c shows a schematic planar view of an array substrate provided by an alternative embodiment of the present disclosure;

FIG. 4 shows a flowchart of a method of manufacturing an array substrate according to an embodiment of the present disclosure;

FIG. 4a shows a specific flowchart of step S402 in FIG. 4 provided by an embodiment of the present disclosure;

FIG. 4b shows a specific flowchart of step S402 in FIG. 4 provided by another embodiment of the present disclosure;

FIGS. 5a to 5e show schematic structural views of an array substrate formed by performing steps of a method of manufacturing an array substrate according to an embodiment of the present disclosure;

FIGS. 6a to 6e show schematic structural views of an array substrate formed by performing steps of a method of manufacturing an array substrate according to another embodiment of the present disclosure;

FIG. 7 shows a schematic structural view of a display device according to an embodiment of the present disclosure.

### DETAILED DESCRIPTION OF EMBODIMENTS

To make the above objectives, features, and advantages of the present disclosure more apparent and easier to understand, the present disclosure will be further described below with reference to the accompanying drawings and embodiments. However, exemplary embodiments can be implemented in various forms and should not be construed as limitation to the embodiments set forth herein; rather, these embodiments are provided so that this disclosure will be more comprehensive and complete, and will fully convey the concept of the exemplary embodiments to those skilled in the art. The same reference numerals in the drawings denote the same or similar structures, and thus their repeated description will be omitted. The expressions of the positions and directions described in this disclosure are all illustrated with the drawings as an example, but changes may be made as needed, and the changes are all included in the scope of the disclosure. The drawings of the present disclosure are only used for illustrating the relative positional relationship, and the layer thicknesses of some parts are illustrated in an exaggerated manner so as to facilitate understanding. The layer thicknesses in the drawings do not represent the proportional relationship of the actual layer thickness.

It should be noted that specific details are set forth in the following description in order to fully understand the present disclosure. However, the present disclosure can be implemented in a variety of other manners different from those described herein, and those skilled in the art can make similar promotions without departing from the content of the present disclosure. Therefore, the present disclosure is not limited by the specific embodiments disclosed below. Certain terms are used throughout the description and claims to refer to particular components. Those skilled in the art will understand that hardware manufacturers may use different terms to refer to the same component. This description and the claims distinguish different components by using functions of the components as the criteria for differentiation, instead of naming. As used throughout the specification and claims, “comprise/comprising” is an open-ended term and it should be interpreted as “include/including but not limited to.” The subsequent description of the specification is intended to embody optional embodiments of the present application. However, the description is intended to illustrate general principles of the present application, instead of limiting the scope of the present application. The scope of protection of this application is defined by the appended claims. It will be understood that when an element such as a layer, film, region, or substrate is defined as being “on” another element, the element can be directly located on the other element, or one or more intervening elements may be intervened.

The present disclosure provides an array substrate, a method of manufacturing the same, and a display panel. The array substrate reflects the external ambient light, so that the display panel is operated in a semi-reflective/semi-transmissive manner, thereby improving the display effect of the display panel in an outdoor environment.

Hereinafter, an array substrate, a method of manufacturing the same, and a display panel provided by an embodiment of the present disclosure will be described in detail by specific embodiments. In the embodiment of the present disclosure, only an array substrate provided with a top-gate thin film transistor having a dual-gate structure is described as an example, but the disclosure is not limited to the array substrate provided with a top-gate thin film transistor having a dual-gate structure. The array substrate may be provided with a single-gate thin film transistor, or the array substrate may be provided with a bottom-gate thin film transistor, which is not specifically limited herein.

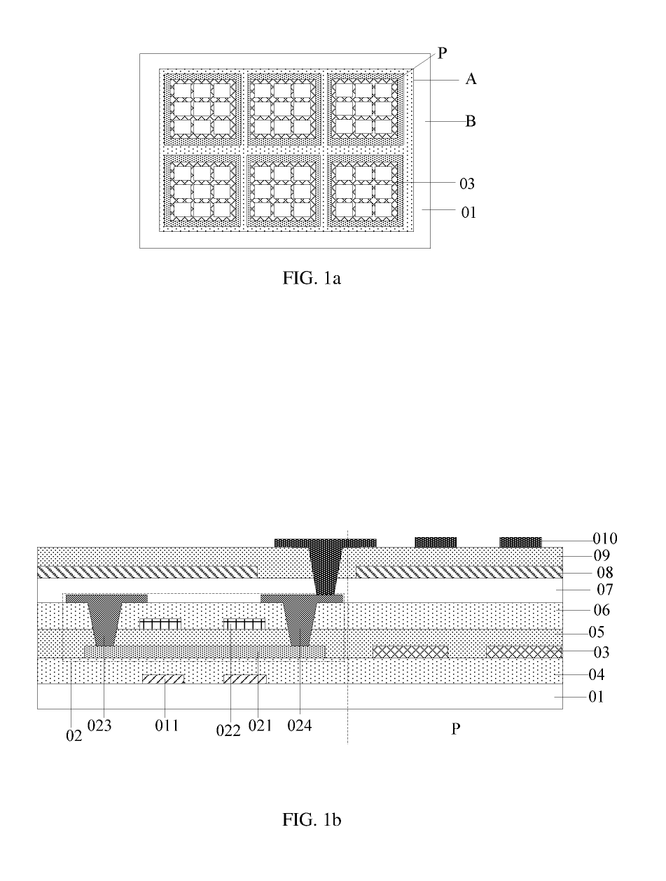

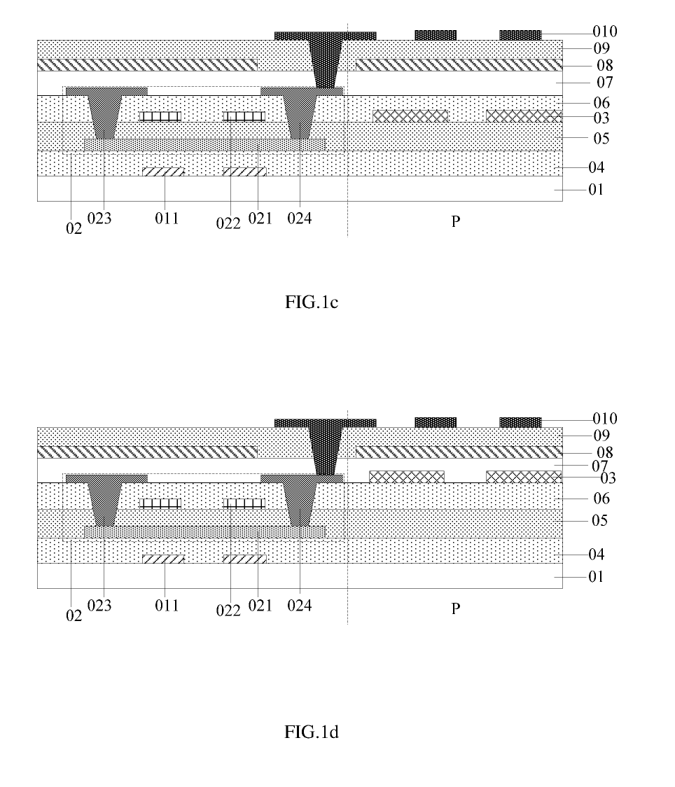

An embodiment of the present disclosure provides an array substrate. FIG. 1a shows a schematic planar view of an array substrate provided by an embodiment of the present disclosure. Referring to FIG. 1a, the array substrate provided by this embodiment includes a base substrate 01 and a plurality of pixel units P disposed on the base substrate 01. The array substrate is divided into a display area A and a periphery area B, i.e., a non-display area, surrounding display area A. The plurality of pixel units P are arranged in the display area, for example, in an array.

FIG. 1b shows a schematic partial cross-sectional view of an array substrate provided by an embodiment of the present disclosure, where only one pixel unit P is shown. Referring to FIG. 1b, the array substrate provided by the embodiment includes a base substrate 01 and a thin film transistor 02 on the base substrate 01. The thin film transistor 02 corresponds to a pixel unit and is configured to control the pixel unit to display. In this embodiment, one pixel unit P corresponds to one thin film transistor 02, and an orthographic projection of the thin film transistor 02 on the base substrate does not substantially overlap an orthogonal projection of the corresponding pixel unit on the base substrate. In other words, the thin film transistor 02 is basically located outside the pixel unit P. The array substrate further includes a reflective layer 03 disposed on the base substrate 01 and located in a part region of the pixel unit P. The reflective layer 03 may reflect external ambient light. In the part region of the pixel unit P where the reflective layer 03 is located, external ambient light is used for displaying. In other part region of the pixel unit P where no reflective layer 03 is located, light emitted from the backlight source is allowed to pass through for displaying.

When a display device having the array substrate provided by this embodiment is used in a strong ambient light environment, such as an outdoor environment, the external ambient light is reflected back out of the display device by the part region of the pixel unit P where the reflective layer 03 is located while the light emitted from the backlight source passes through the other part region of the pixel unit P where no reflective layer 03 is located. Thereby, the external ambient light is effectively used for displaying, and the problems such as high power consumption, short service life, and damage to eyes of a display in which only the light emitted from the backlight source is used for displaying may be avoided.

In this embodiment, the reflective layer 03 is, for example, a metal reflective layer. The thin film transistor 02 includes a gate electrode, an active layer, and a source/drain electrode. The metal reflective layer 03 may be disposed in a same layer as and insulated from any of the gate electrode, the active layer, and the source/drain electrode of the thin film transistor 02.

Specifically, the thin film transistor 02 includes the active layer 021, the gate electrode 022 and a source/drain electrode including a source electrode 023 and a drain electrode 024, which are disposed on the base substrate 01 in that order. The metal reflective layer 03 in the embodiment of the present disclosure may be disposed in the same layer as any of the active layer 021, the gate electrode 022, and the source/drain electrode of the thin film transistor 02. For example, as shown in FIG. 1 b, the metal reflective layer 03 may be disposed in the same layer as the active layer 021 and insulated from that. FIG. 1c shows a schematic partial cross-sectional view of an array substrate provided by an alternative embodiment of the present disclosure, in which only one pixel unit P is shown. As shown in FIG. 1c, the metal reflective layer 03 may be disposed in the same layer as and insulated from the gate electrode 022. FIG. 1d shows a schematic partial cross-sectional view of an array substrate provided by an alternative embodiment of the present disclosure, in which only one pixel unit P is shown. As shown in FIG. 1d, the metal reflective layer 03 may also be disposed in the same layer as the source/drain electrode including the source electrode 023 and the drain electrode 024 and insulated from that.

It should be noted that, in the above embodiments of the present disclosure, the part region of the pixel unit P where the reflective layer 03 is located reflects external ambient light so as to effectively utilize the external ambient light to achieve brighter display, meanwhile the part region of the pixel unit P where no reflective layer 03 is located allows the light emitted from the backlight source to pass through for displaying, so that the display panel having the above-mentioned array substrate may displays in a semi-reflective/semi-transmissive manner. In order to further ensure a transmission aperture ratio of the array substrate in the semi-reflective/semi-transmissive manner, the metal reflective layer 03 may be set to be small as possible, while the part region of the pixel unit P where no reflective layer 03 is located is set to be large as possible, thereby ensuring a normal transmission aperture ratio of the array substrate.

Therefore, an array substrate provided by an embodiment of the present disclosure includes a display area, in which a plurality of pixel units P are disposed. The array substrate includes: a base substrate, a thin film transistor disposed on the base substrate; and a metal reflective layer disposed on the base substrate and located in a part region of the pixel unit P. The metal reflective layer includes a reflective region that reflects light from the ambient environment. The metal reflective layer may be arranged in the same layer and insulated from any layer of the thin film transistor, such as a gate electrode, an active layer or a source/drain electrode. Therefore, when a display device having the array substrate provided by this embodiment is used in a strong ambient light environment, such as an outdoor environment, the light emitted from the backlight source passes through the part region of the pixel unit P where no reflective layer 03 is located, and the external ambient light is reflected back out of the display device by the part region of the pixel unit P where the reflective layer 03 is located, thereby the external ambient light may be effectively used for displaying, and the problems such as high power consumption, short service life, and damage to eyes of a display panel in which only the light emitted from the backlight source is used for displaying may be avoided.

In addition, in the present disclosure, the metal reflective layer and any layer of the thin film transistor may be arranged in the same layer and insulated from each other, so that the arrangement of the metal reflective layer does not affect the normal operation of other electrodes, such as pixel electrode, common electrode and the like, in the display area. It can be seen that the array substrate provided by the present disclosure may reflect external ambient light, so that the array substrate may perform displaying in the semi-reflective/semi-transmissive manner, thereby improving the display performance of the display panel in the outdoor environment.

Specifically, in the array substrate provided by the embodiment of the present disclosure, as shown in FIG. 1b, FIG. 1c, or FIG. 1d, the array substrate further includes: a buffer layer 04 disposed between the base substrate 01 and the active layer 021, a gate insulating layer 05 disposed between the active layer 021 and the gate electrode 022, an interlayer dielectric layer 06 disposed between the gate electrode 022 and the source/drain electrode including the source electrode 023 and the drain electrode 024, and an organic film layer 07, an common electrode 08, an passivation layer 09, and an pixel electrode 010 which are disposed in that order on or over the source/drain electrode including the source electrode 023 and the drain electrode 024. The pixel electrode 010 is electrically connected to the drain electrode 024 through a via hole that penetrates the passivation layer 09 and the organic film layer 07. In addition, in order to shield a channel region of the active layer 021 corresponding to the gate electrode 022, the array substrate further includes a light shielding layer 011 disposed between the buffer layer 04 and the base substrate 01. The light shielding layer 011 is disposed to prevent the light emitted from the backlight source from irradiating the channel region of the active layer 021, so as to prevent the light from degrading the channel region and thus degrading the characteristics of the thin film transistor.

Specifically, the metal reflective layer 03 in the embodiment of the present disclosure is located within the pixel unit P. In addition, the pixel electrode 010 is generally located within the pixel unit P to achieve normal display. Therefore, the metal reflective layer 03 may overlap the pixel electrode 010. Since the metal reflective layer 03 is disposed in the same layer as any layer of the thin film transistors, it does not apply interference to an electric signal of the pixel electrode or the common electrode in the display area. Further, since an insulating layer such as the organic film layer and/or the passivation layer is provided between the pixel electrode or the common electrode and the metal reflective layer, signal coupling or interference to the pixel electrode or the common electrode layer is reduced.

In an embodiment, the metal reflective layer 03 and the active layer 021 are disposed in the same layer and insulated from each other, as shown in FIG. 1b. In order to avoid the switching characteristics between the active layer 021 and the gate electrode 022 in the array substrate to be affected during forming the metal reflective layer or during processing the metal reflective layer when forming the metal reflective layer, for example a pretreatment such as inert gas bombardment and the like, a pattern of the metal reflective layer is formed before or after a formation of a pattern of the active layer.

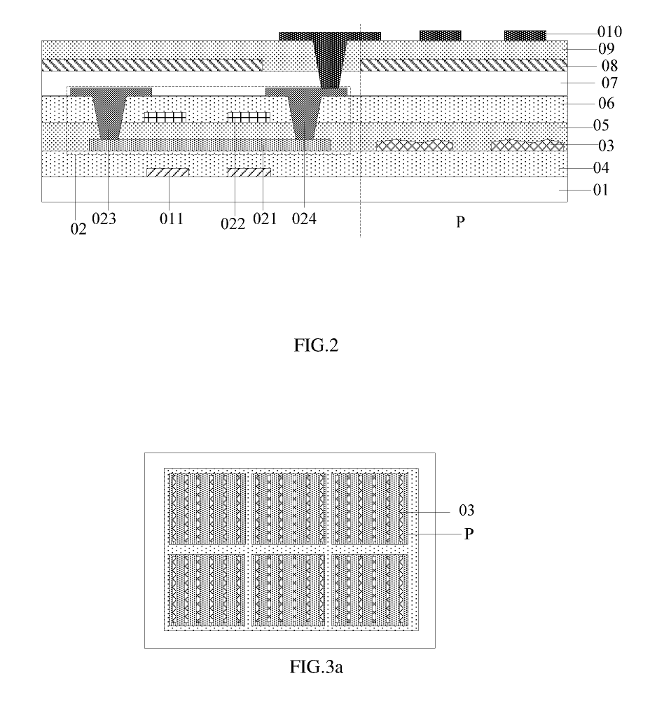

Another embodiment of the present disclosure provides an array substrate. FIG. 2 is a schematic partial cross-sectional view of an array substrate provided by another embodiment of the present disclosure. In this embodiment, in order to further improve reflective properties of the metal reflective layer, as shown in FIG. 2, a surface of the metal reflective layer 03 facing away from the base substrate 01 includes a rugged structure. The metal reflective layer having the rugged surface involves a diffuse reflection of the external ambient light, so that the reflected light is more evenly, the external ambient light may be effectively used, and thus display performance is improved.

The reflective layer may be made of a metal material or a non-metal material. In the embodiments of the present disclosure, description is made by referring to example of the metal material such as silver, aluminum, molybdenum, or titanium. In an embodiment, the metal reflective layer is formed in the same layer as the gate electrode, the metal reflective layer may be formed from the same material as the gate electrode through a single patterning process, thereby saving manufacturing processes. In an embodiment, the metal reflective layer is formed in the same layer as the source electrode or the drain electrode, the metal reflective layer may be formed from the same material as the source/drain electrode through a single patterning process, thereby saving manufacturing processes.

In an embodiment, the metal reflective layer is made of silver. Compared with other metal materials, silver has more excellent reflective property, and thus may further improves the reflective properties of the metal reflective layer. Therefore, silver may be used for forming the metal reflective layer.

It should be noted that “components are disposed/formed in the same layer” described in the embodiments of the present disclosure may mean the components are the structures which are formed at the same time from the same material or the structures which are formed at different time from the same material. For example, the reflective layer and the gate electrode may be formed from the same metal material through the single patterning process at the same time. For example, the reflective layer is made of a metal material such as silver, and is disposed in the same layer as the active layer, that is, the active layer and the metal reflective layer are at the same level. Alternatively, the the metal reflective layer may be formed before or after the formation of the active layer.

In an embodiment, as shown in FIG. 1a, the metal reflective layer 03 is disposed in the part region of the pixel unit P, and is absent in the other part region of the pixel unit P. That is, the metal reflective layer 03 may be regarded as an entire metal reflective layer with a plurality of hollow structures as shown in FIG. 1a.

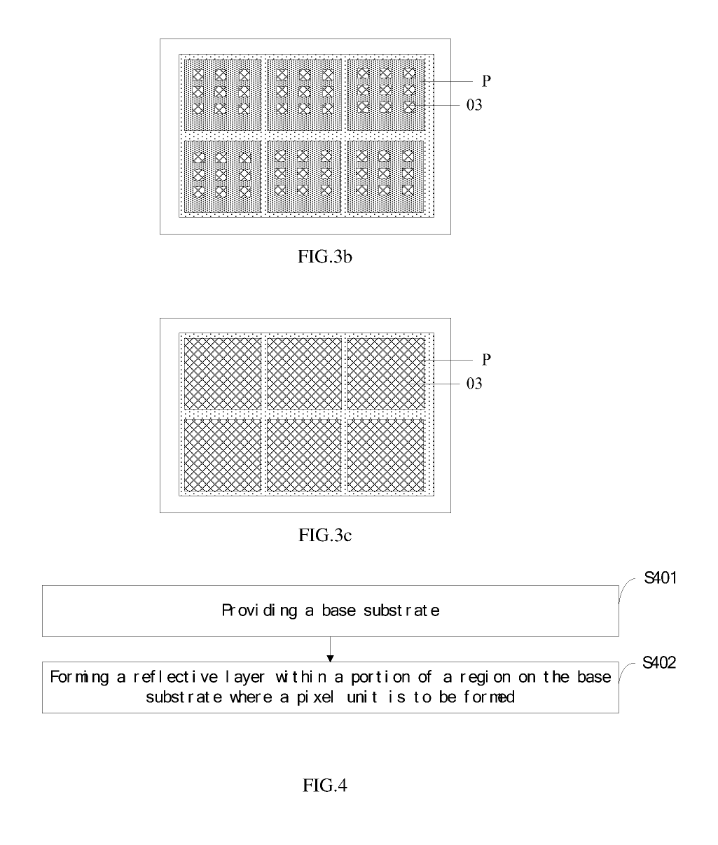

FIG. 3 a is a schematic planar view of an array substrate provided by an alternative embodiment of the present disclosure. As shown in FIG. 3a, a metal reflective layer 03 is configured as a plurality of strip structures spaced away from one another, i.e., a plurality of sub reflective layers. A gap between two adjacent strip structures allow light emitted from the backlight source to pass through. FIG. 3b is a schematic planar view of an array substrate provided by an alternative embodiment of the present disclosure. As shown in FIG. 3b, a metal reflective layer 03 is configured as a plurality of block structures spaced away from one another, i.e., a plurality of sub reflective layers. A gap between two adjacent block structures allow light emitted from the backlight source to pass through. FIG. 3c is a schematic planar view of an array substrate provided by an alternative embodiment of the present disclosure. As shown in FIG. 3c, a metal reflective layer 03 is disposed on the entire region of the pixel unit P. At this time, the metal reflective layer 03 is so thin that the metal reflective layer 03 has semi-reflective/semi-transmissive characteristics, that is, it may reflect the external ambient light while allow the light emitted from the backlight source to pass through.

It should be noted that the size of the metal reflective layer in the present disclosure can be designed according to actual requestments, an proportion of area of the metal reflective layer in the pixel unit P can be adjusted and designed according to a transmission aperture ratio of the display area in the array substrate. For example, in order to prevent the metal reflective layer from affecting normal display of display region, the proportion of area of the metal reflective layer in the pixel unit P can be properly reduced.

In the foregoing embodiments, as shown in FIGS. 1b-1d and FIG. 2, the array substrate is an FFS (Fringe Field Switching) array substrate, which includes a pixel electrode and a common electrode, and in which a passivation layer is provided between the pixel electrode and the common electrode. In aother embodiment, the array substrate may also be an IPS (In Plane Switching) array substrate, a TN (Twisted Nematic) array substrate, or the like. In an IPS (In Plane Switching) array substrate, the pixel electrodes and the common electrodes are arranged in the same layer alternately. In a TN (Twisted Nematic) array substrate, only pixel electrodes are provided in the array substrate, and no common electrode is provided.

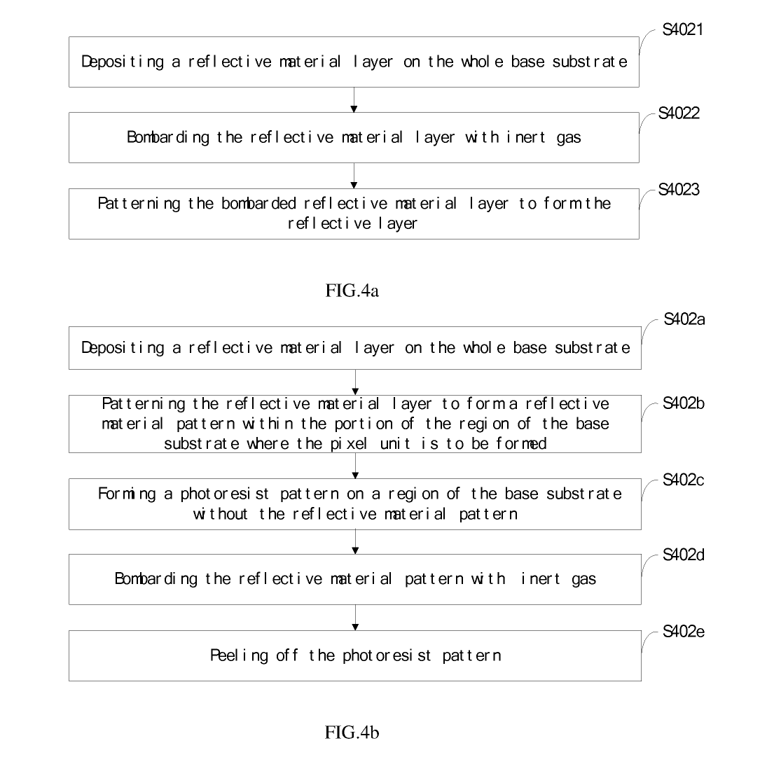

A method of manufacturing an array substrate is provided by an embodiment of the present disclosure. FIG. 4 is a flowchart of a method of manufacturing an array substrate according to an embodiment of the present disclosure. In the method of this embodiment, in order make the reflective layer with a rugged structure so as to improve reflection effects for the external ambient light, it is necessary to pretreat the reflective material forming the reflective layer, for example, bombarding the surface of the reflective material with inert gas. Referring to FIG. 4, the method includes the following steps:

S401, providing a base substrate;

S402, forming a reflective layer within a portion of a region on the base substrate where a pixel unit is to be formed.

FIG. 4a is a specific flowchart of the step of forming the reflective layer in FIG. 4 provided by an embodiment of the present disclosure. As shown in FIG. 4a, the step of forming the reflective layer includes:

S4021, depositing a reflective material layer on the whole base substrate;

S4022, bombarding the reflective material layer with inert gas; and

S4023, patterning the bombarded reflective material layer to form the reflective layer.

FIG. 4b is a specific flowchart of the step of forming the reflective layer in FIG. 4 provided by another embodiment of the present disclosure. As shown in FIG. 4b, the step of forming the reflective layer includes:

S402a, depositing a reflective material layer on the whole base substrate;

S402b, patterning the reflective material layer to form a reflective material pattern within the portion of the region of the base substrate where the pixel unit is to be formed.

S402c, forming a photoresist pattern on a region of the base substrate without the reflective material pattern;

S402d, bombarding the reflective material pattern with inert gas;

S402e, peeling off the photoresist pattern.

In the embodiments of the present disclosure, the reflective layer may be made of a metal material or a non-metal material. In some embodiments of the present disclosure, description is made by referring examples of the metal material such as silver, aluminum, molybdenum, or titanium.

In an embodiment, the method for manufacturing the array substrate further includes forming a thin film transistor on the base substrate. Specifically, a gate electrode, an active layer, a source/drain electrode are formed on a base substrate. The orders of formations of layers varies in different types of thin film transistors. The metal reflective layer may be disposed in the same layer as and insulated from any of layers of the thin film transistor, such as the gate electrode, the active layer or the source/drain electrode. The metal reflective layer may reflect external ambient light, and is disposed in a part region of the pixel unit P on the base substrate. Another part region of the pixel unit P where no metal reflective layer is disposed has a transmission property for the light emitted from the backlight source.

Specifically, the step of forming the thin film transistor on the base substrate includes forming the active layer, the gate electrode, and the source/drain electrode on the base substrate. In an embodiment of the present disclosure, the metal reflective layer may be disposed in the same layer as the gate electrode and made of the same material, such as silver as the gate electrode. In this case, the metal reflective layer and the gate electrode may be simultaneously formed by a single patterning process. Optionally, the metal reflective layer may be made of a material different from the gate electrode, and may be formed before or after forming the gate electrode. In another embodiment of the present disclosure, the metal reflective layer may be disposed in the same layer, and made of the same material, such as silver, as the source/drain electrode. In this case, the metal reflective layer and the source/drain electrode may be simultaneously formed by a single patterning process. Optionally, the metal reflective layer may be made of a material different from the source/drain electrode. In this case, the metal reflective layer may be formed before or after forming the source/drain electrode. In another embodiment of the present disclosure, the metal reflective layer may be disposed in the same layer as the active layer, and formed before or after forming the active layer.

Therefore, in the array substrate manufactured by the method for manufacturing the array substrate according to the above embodiment of the present disclosure, the metal reflective layer is formed in the part region of the pixel unit P, such that the light emitted from the backlight source passes through the other part region of the pixel unit P, where no metal reflective layer is disposed, for displaying, while the external ambient light is reflected by the metal reflective layer, replacing the light emitted from the backlight source, for displaying in the part region of the pixel unit P where the metal reflective layer is provided. Therefore, the external ambient light may be effectively used for display and the problems of a display panel in which only light from a backlight is used for displaying, such as high power consumption, short life, and damage to eyes may be avoided. The array substrate provided by the present disclosure reflects external ambient light, so that the array substrate displays in the semi-reflective/semi-transmissive manner, thereby improving the display effect of the display panel in the outdoor environment.

In addition, according to the method of manufacturing the array substrate in an embodiment of the present disclosure, the metal reflective layer is disposed in the same layer as and insulated from any of the layers of the thin film transistor such as the gate electrode, the active layer, and the source/drain electrode, so that the arrangement of the metal reflective layer does not affect the normal operation of other electrodes in the display area, such as pixel electrode, common electrode and the like. In the method of manufacturing the array substrate provided in the foregoing embodiments of the present disclosure, the metal reflective layer may be disposed in the same layer as the active layer, thereby avoiding electrical connection between the metal reflective layer and at least one of the gate electrode and the source/drain electrode, and then avoiding affecting the normal operation of the thin film transistor of the array substrate. The metal reflective layer may also be disposed in the same layer as and insulated from the gate electrode such that the metal reflective layer and the gate electrode may be formed through a single patterning process, thereby simplifying the manufacturing processes. The metal reflective layer may also be disposed in the same layer as and insulated from the source/drain electrode, such that the metal reflective layer and the source/drain electrode may be formed through a single patterning process, thereby simplifying the manufacturing processes.

Specifically, during the formation of the metal reflective layer, in order to further improve the reflective properties of the metal reflective layer, the surface of the the metal reflective layer facing away from the base substrate may be formed to include a rugged structure. Therefore, the step of forming the metal reflective layer further includes: pretreating the surface of the deposited metal reflective material layer or the patterned metal reflective material layer facing away from the base substrate to form the metal reflective layer with the rugged structure, so that light reflected by the metal reflective layer is more evenly, and thus the external ambient light may be effectively used, thereby improving the display performance.

The method of manufacturing the array substrate will be described below by taking the array substrate with a top-gate and dual-gate thin film transistor as an example. The step and method of forming the metal reflective layer will be described by take an example of forming the metal reflective layer after forming the active layer of the thin film transistor and before forming the gate electrode of the thin film transistor. However, the present disclosure does not limit that the metal reflective layer is formed after forming the active layer. In aother embodiment, the metal reflective layer may be formed after forming the gate electrode or the the source/drain electrode.

In an embodiment, in a method of manufacturing the array substrate provided by the embodiment of the present disclosure, during forming the thin film transistor on the base substrate, forming the metal reflective layer on the base substrate by the patterning process includes: after forming the active layer of the thin film transistor on the base substrate, forming the metal reflective layer on the base substrate on which the active layer is formed. The surface of the the metal reflective layer facing away from the base substrate includes the rugged structure.

Specifically, in the method of manufacturing the array substrate provided by an embodiment of the present disclosure, the step of forming a metal reflective layer on the base substrate on which the active layer is formed can be implemented in various ways.

For example, in an embodiment, the step of forming the metal reflective layer includes: depositing a metal reflective material layer on entire surface of the base substrate on which the active layer is formed; pretreating the metal reflective material layer so that a surface of the metal reflective material layer includes a rugged structure; coating the metal reflective material layer having a rugged surface with a first photoresist layer; forming a first photoresist completely reserved region corresponding to a region where the metal reflective layer is to be formed and a first photoresist completely removed region after exposuring and developing the first photoresist layer; removing the metal reflective material layer corresponding to the first photoresist completely removed region by etching. In this way, the metal reflective material layer covering the entire base substrate is pretreated so that the surface of the metal reflective material layer becomes rugged, thereby increasing roughness of the surface of the metal reflective material layer and thus achieving a diffuse reflection. The metal reflective layer is formed by depositing a photoresist layer, and processes of exposing, developing, and etching the metal reflective material layer after it is roughened. After development, the first photoresist completely reserved region corresponds to the region where the metal reflective layer is to be formed, and the first photoresist completely removed region corresponds to the rest region where no metal reflective layer is to be formed.

For example, in another embodiment, the step of forming the metal reflective layer includes: depositing a metal reflective material layer on a surface of the base substrate on which the active layer is formed; coating the metal reflective material layer with a first photoresist layer; forming a first photoresist completely reserved region corresponding to a region where the metal reflective layer is to be formed and a first photoresist completely removed region corresponding to the rest region where no metal reflective layer is to be formed after exposuring and developing the first photoresist layer; etching the metal reflective material layer corresponding to the first photoresist completely removed region and peeling off the first photoresist layer in first photoresist completely reserved region; then pretreating the reserved metal reflective material layer (i.e. a metal reflective material pattern), so that a surface of the reserved metal reflective material layer includes a rugged structure. That is, the metal reflective material pattern is pretreated after it is formed so that the surface of the metal reflective material pattern is rugged, thereby increasing a roughness of the surface of the metal reflective material pattern, and achieving a diffuse reflection.

In the above another embodiment, specifically, the step of forming the metal reflective layer further includes: after forming the metal reflective material pattern and peeling off the first photoresist layer in the first photoresist completely reserved region, forming a second photoresist pattern on a region of the base substrate on which the metal reflective material pattern is not formed, that is, the second photoresist pattern exposes the metal reflective material pattern while covering the rest region; pretreating the metal reflective material pattern. In this way, when the metal reflective material pattern is pretreated, the rest region, such as a region including the active layer, may be protected by the second photoresist pattern, and thus is not affected by pretreatment of the metal reflective material pattern. The step of forming the second photoresist pattern includes: entirely forming a second photoresist layer on the base substrate on which the active layer and the metal reflective material pattern are formed, the second photoresist layer being made of a positive or negative material; exposing and developing the second photoresist layer to form a second photoresist completely reserved region (i.e. the second photoresist pattern) and a second photoresist completely removed region, the second photoresist completely removed region corresponding to the region in which the metal reflective material pattern is formed, the second photoresist completely reserved region corresponding to the region in which the metal reflective material pattern is not formed and including at least the region in which the active layer is included. Finally, the base substrate on which the second photoresist pattern is formed is pretreated. Since the second photoresist pattern may protect the active layer, when the metal reflective material pattern is pretreated, the active layer is avoided from influence of the pretreatment.

Specifically, in the method of manufacturing the array substrate provided by an embodiment of the present disclosure, the pretreatment includes physically bombarding the metal reflective material layer with inert gas. Specifically, the inert gas may be gas of such as He, Ar or the like. The metal reflective material layer is physically bombarded with the inert gas, so that the surface of the metal reflective material layer is formed with the rugged structure. Moreover, due to the use of the inert gas, the metal reflective material layer may not be oxidized during pretreatment of the metal reflective material layer. Persons skilled in the art can understand that, in the present disclosure, the pretreatment may also be performed in another manner, so that the surface of the metal reflective material layer is formed with the rugged structure.

Specifically, in the method of manufacturing the array substrate provided by the embodiment of the present disclosure, the exposed metal reflective material layer corresponding to the first photoresist completely removed region is removed by a wet etching process. Specifically, the metal reflective material layer is etched by a wet etching process, such as, using a mixed solution of nitric acid and phosphoric acid.

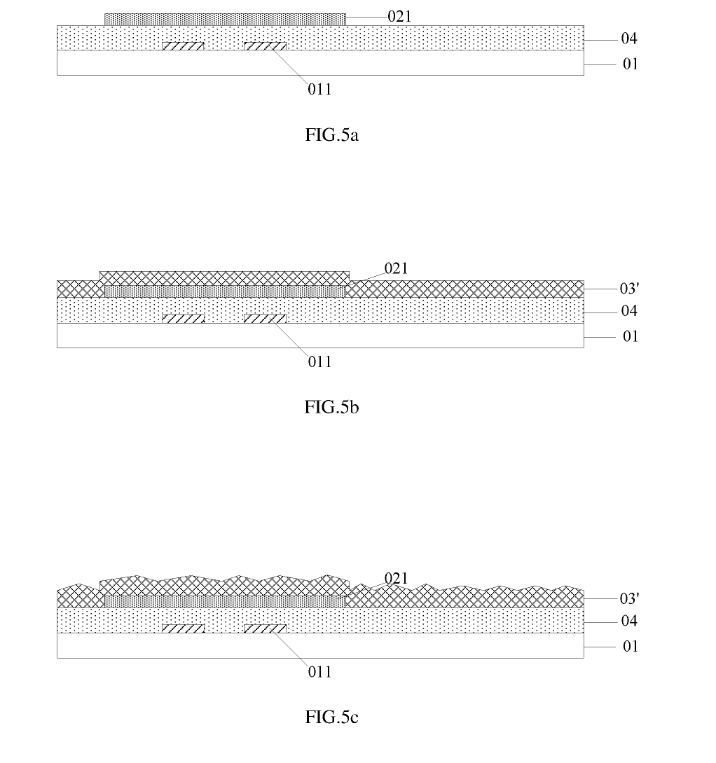

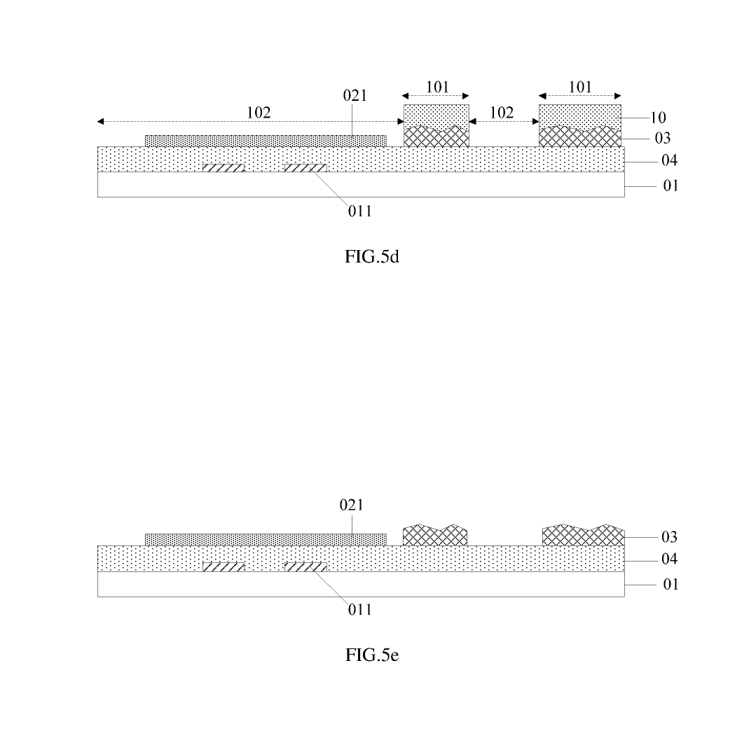

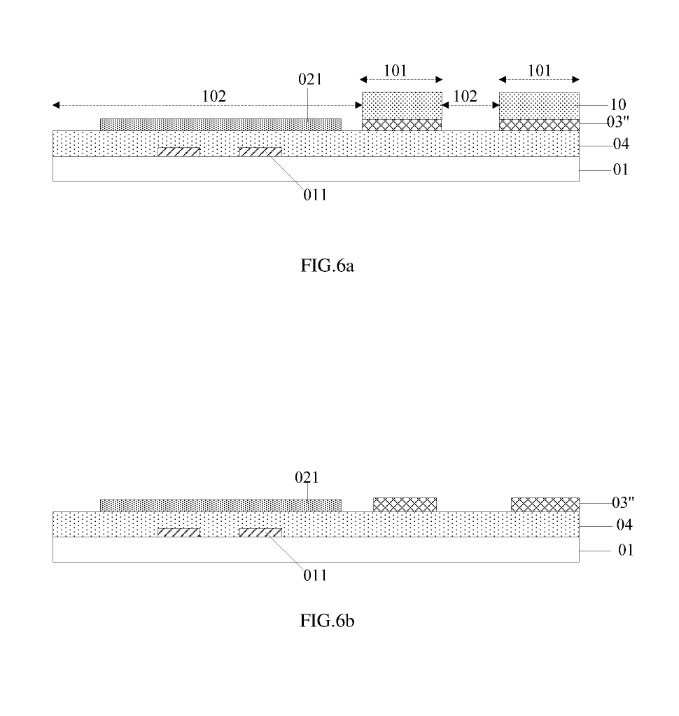

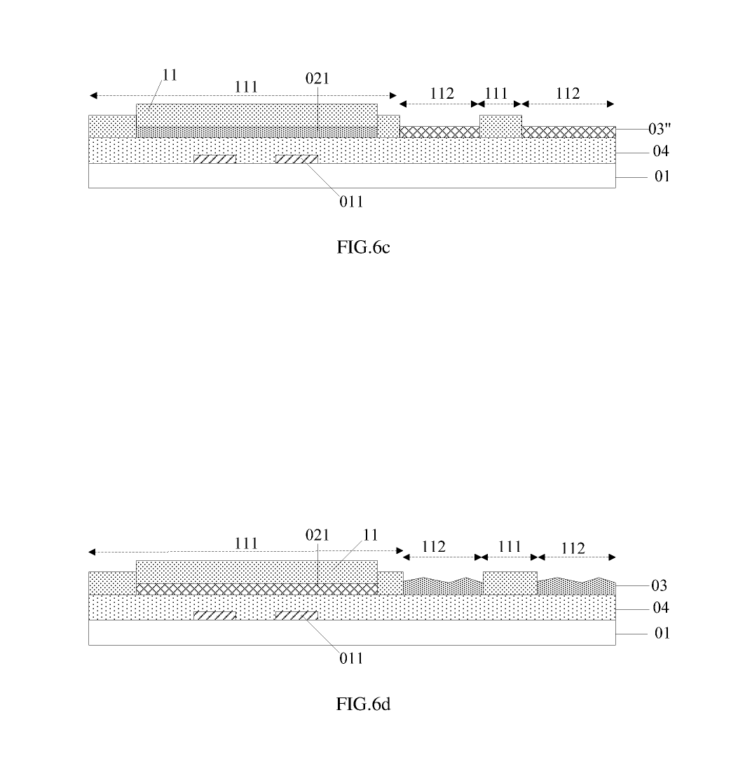

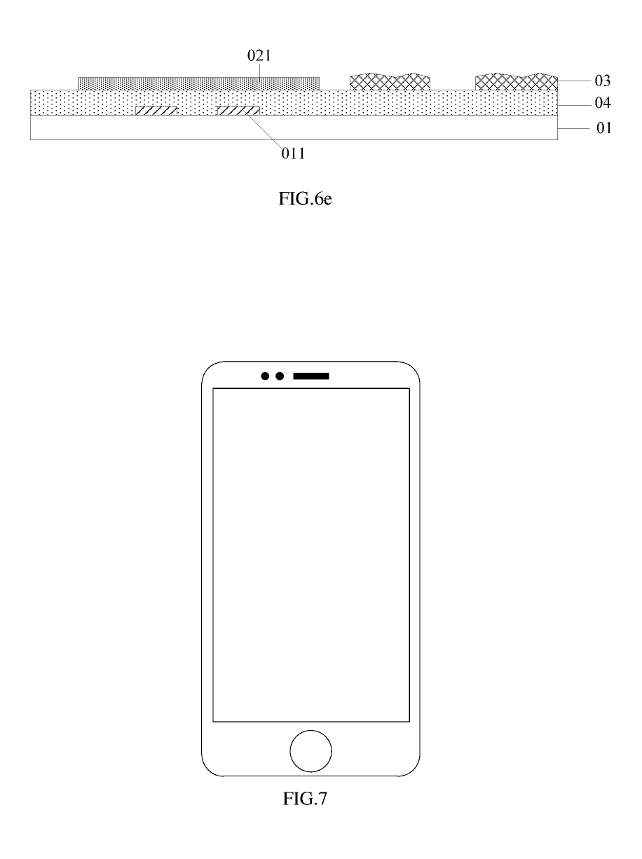

The method of manufacturing the array substrate will be described below in detail in conjunction with the accompanying drawings. The method will be described by take the embodiment where the metal reflective layer is formed after forming the active layer as an example, with reference to FIGS. 5a-5e and FIGS. 6a-6e. FIGS. 5a to 5e respectively show schematic structural views of an array substrate formed by performing steps of a method of manufacturing an array substrate according to an embodiment of the present disclosure, and FIGS. 6a to 6e respectively show schematic structural views of an array substrate formed by performing steps of a method of manufacturing an array substrate according to another embodiment of the present disclosure. In these embodiments, the thin film transistor is a top-gate and dual-gate thin film transistor.

In an embodiment, the method of manufacturing the array substrate includes the following steps of:

S501, forming a light shielding layer 011, a buffer layer 04, and an active layer 021 in that order on a base substrate 01, as shown in FIG. 5a;

S502, forming a metal reflective material layer 03′ on the base substrate 01 on which the active layer 021 is formed, as shown in FIG. 5b, for example, the metal reflective material layer being formed by depositing.

S503, physically bombarding the metal reflective material layer 03′ with inert gas such that a surface of the metal reflective material layer is formed with a rugged structure, as shown in FIG. 5c;

S504, forming a first photoresist layer 10 on the base substrate shown in FIG. 5c, exposing and developing the first photoresist layer 10 to form a first photoresist completely reserved region 101 corresponding to a region where the metal reflective layer 03 is to be formed and a first photoresist completely removed region 102, and then etching off the exposed metal reflective material layer corresponding to the first photoresist completely removed region 102, as shown in FIG. 5d;

S505, peeling off the first photoresist layer 10 in the first photoresist completely reserved region 101, as shown in FIG. 5e;

S506, forming a gate insulating layer 05, a gate electrode 022, an interlayer dielectric layer 06, and a source/drain electrode including a source electrode 023 and a drain electrode 024 in this order on the base substrate shown in FIG. 5e; then forming an organic film layer 07, an common electrode 08, an passivation layer 09 and a pixel electrode 010 in that order on the source/drain electrode, the pixel electrode 010 being electrically connected to the drain electrode 024 through a via hole penetrating the organic film layer 07 and the passivation layer 09, as shown in FIG. 2.

In another embodiment, the method of manufacturing the array substrate includes the following steps of:

S601, forming a light shielding layer 011, a buffer layer 04, and an active layer 021 in that order on a base substrate 01, as shown in FIG. 5a, in the same way as S501.

S602, forming a metal reflective material layer on the base substrate 01 on which the active layer 021 is formed, as shown in FIG. 5b, in the same way as S502.

S603, forming a first photoresist layer 10 on the base substrate shown in FIG. 5b, exposing and developing the first photoresist layer 10 to form a first photoresist completely reserved region 101 corresponding to a region where the metal reflective layer 03 is to be formed and a first photoresist completely removed region 102, and then etching off the exposed metal reflective material layer 03′ corresponding the first photoresist completely removed region 102 to form a metal reflective material pattern 03″, as shown in FIG. 6a;

S604, peeling off the first photoresist layer 10 in the first photoresist completely reserved region, as shown in FIG. 6b;

S605, forming a second photoresist layer 11 on the base substrate shown in FIG. 6b, exposing and developing the second photoresist layer 11 to form a second photoresist completely reserved region 111, covering at least the active layer 02, and a second photoresist completely removed region 112, as shown in FIG. 6c;

S606, physically bombarding the metal reflective material pattern 03″ on the base substrate shown in FIG. 6c with inert gas to form a rugged structure for a surface of the metal reflective material pattern 03″, i.e., obtaining a metal reflective layer 03, as shown in FIG. 6D;

S607, peeling off the second photoresist layer 11 in the second photoresist completely reserved region 111, as shown in FIG. 5e;

S608, forming a gate insulating layer 05, a gate electrode 022, an interlayer dielectric layer 06, and a source/drain electrode including a source electrode 023 and a drain electrode 024 in this order on the base substrate shown in FIG. 6e; then forming an organic film layer 07, an common electrode 08, an passivation layer 09 and a pixel electrode 010 in that order on the source/drain electrode, the pixel electrode 010 being electrically connected to the drain electrode 024 through a via hole penetrating the organic film layer 07 and the passivation layer 09, as shown in FIG. 2.

Specifically, in the former embodiment, when the metal reflective material layer is physically bombarded, since the metal reflective material layer covers the active layer, the active layer is prevented from being damaged during the pretreatment. In the latter embodiment, when the metal reflective material pattern is physically bombarded, the active layer and the buffer layer are protected by the second photoresist pattern from being damaged during the pretreatment.

It should be noted that, in the method of manufacturing the array substrate provided by the embodiment of the present disclosure, the patterning process may includes any patterning method, for example, a method including exposing, developing and etching by using the photoresist. In this method, it is specifically included steps of, but are not limited to, applying the photoresist, exposing with a mask, developing, and etching a layer that needs to be patterned to form a corresponding pattern. For the patterning processes that are performed by multiple times, it is not limited they include the same process steps. For example, a patterning process for the passivation layer may include steps of applying photoresist, exposing, developing, and etching.

An embodiment of the present disclosure further provides a display panel including any one of the above-mentioned array substrates provided by the foregoing embodiments of the present disclosure. The display panel includes the same technical features and involves the same beneficial effects as the array substrate respectively, and the similar aspects are not repeatedly described.

An embodiment of the present disclosure further provides a display device including the above-mentioned display panel provided by the foregoing embodiment of the present disclosure. FIG. 7 shows a schematic structural view of a display device according to an embodiment of the present disclosure. The display device may be any one of products or components having display function, such as a mobile phone (as shown in FIG. 7), a tablet computer, a television, a monitor, a notebook computer, a digital photo frame, a navigator, and the like. Embodiments of the display device may be referred to the above embodiments of the array substrate, and repeated description is omitted.

It will be apparent to those skilled in the art that various modifications and variations can be made in the present disclosure without departing from the spirit and scope of the disclosure. Thus, if these modifications and variations of the present disclosure fall within the scope of the claims of the present disclosure and their equivalent technologies, the present disclosure also intends to include these modifications and variations.

What is claimed is:

1. An array substrate comprising:
a base substrate, and
a pixel unit on the base substrate; and
a reflective layer disposed on the base substrate and located in a portion of a region of the pixel unit,
wherein, a surface of the reflective layer facing away from the base substrate comprises a rugged structure.

2. The array substrate according to claim 1, wherein the reflective layer is made of a metal material.

3. The array substrate according to claim 2, wherein the reflective layer is made of silver.

4. The array substrate according to claim 1, further comprising:
a pixel electrode disposed on the base substrate and located in the pixel unit,
wherein the reflective layer is disposed between the pixel electrode and the base substrate.

5. The array substrate according to claim 4, further comprising:
a thin film transistor on the base substrate,
wherein the thin film transistor comprises a gate electrode, an active layer, and a source/drain electrode,
wherein the reflective layer is disposed in a same layer as any one of the gate electrode, the active layer, and the source/drain electrode.

6. The array substrate according to claim 5, wherein the reflective layer is disposed in the same layer as the active layer.

7. The array substrate according to claim 5, wherein the thin film transistor is a top-gate thin film transistor, and the array substrate further comprises:
a light shielding layer between the thin film transistor and the base substrate;
wherein an orthogonal projection of the gate electrode on the base substrate is located within an orthogonal projection of the light shielding layer on the base substrate or the orthogonal projection of the gate electrode on the base substrate coincides the orthogonal projection of the light shielding layer on the base substrate.

8. The array substrate according to claim 5, wherein the thin film transistor is a dual-gate thin film transistor.

9. The array substrate of claim 4, further comprising:
at least one of a passivation layer and an organic film layer provided between the reflective layer and the pixel electrode.

10. The array substrate of claim 1, wherein the reflective layer in the pixel unit comprises a plurality of sub reflective layers spaced away from one another.

11. The array substrate according to claim 1, wherein the reflective layer in the pixel unit is in a mesh-like shape.

12. A display panel, comprising the array substrate according to claim 1.

13. A method of manufacturing an array substrate, comprising:
providing a base substrate; and
forming a reflective layer within a portion of a region of the base substrate where a pixel unit is to be formed,
wherein, a surface of the reflective layer facing away from the base substrate comprises a rugged structure.

14. The method of claim 13, wherein the step of forming a reflective layer within a portion of a region of the base substrate where a pixel unit is to be formed comprises:
depositing a reflective material layer on the whole base substrate;
bombarding the reflective material layer with inert gas; and
patterning the bombarded reflective material layer to form the reflective layer.

15. The method of claim 13, wherein the step of forming a reflective layer within a portion of a region of the base substrate where a pixel unit is to be formed comprises:
depositing a reflective material layer on the whole base substrate;
patterning the reflective material layer to form a reflective material pattern within the portion of the region of the base substrate where the pixel unit is to be formed;
forming a photoresist pattern in a region of the base substrate where the reflective material pattern is not formed;
bombarding the reflective material pattern with inert gas; and
peeling off the photoresist pattern.

16. The method of claim 13, further comprising:
forming a thin film transistor on the base substrate,
wherein the thin film transistor comprises a gate electrode, an active layer, and a source/drain electrode,
wherein the reflective layer is formed in a same layer as any one of the gate electrode, the active layer, and the source/drain electrode.

17. The method according to claim 16, before forming a reflective layer within a portion of a region of the base substrate where a pixel unit is to be formed, the method further comprises:
forming the active layer of the thin-film transistor by a patterning process,
wherein, the reflective layer is formed in the same layer as the active layer of the thin film transistor.

18. The method according to claim 13, after forming a reflective layer within a portion of a region of the base substrate where a pixel unit is to be formed, the method further comprises:
forming a pixel electrode within the region of the base substrate where the pixel unit is to be formed.
